(19) United States
(12) Patent Application Publication
(10) Pub. No.: US 2007/0273420 A1
(43) Pub. Date: Nov. 29, 2007

(54) METHOD AND APPARATUS FOR A LOW STANDBY-POWER FLIP-FLOP

(76) Inventors: Pavan Vithal Torvi, Bangalore (IN); Sujan Manohar, Kundapur (IN)

Correspondence Address: TEXAS INSTRUMENTS INCORPORATED, P O BOX 655474, M/S 3999, DALLAS, TX, 75265, US

(21) Appl. No.: 11/419,766

(22) Filed: May 23, 2006

(51) Int. Cl. H03K 3/289

(52) U.S. Cl. 327/202

(57) ABSTRACT

A flip-flop is configured for low standby/leakage power for power-conservation, especially in battery operated portable devices using flip-flops. The flip-flop uses a clock and may be a D flip-flop, including a master latch with first and second inverters and a slave latch. The inverters in the master-latch are configured to be selectively gated. The gating is preferably done by first and second transistors receiving the clock signal and connected between a voltage source and the ground. The gating cuts off power supply to the inverters when the clock is low and reduces leakage power. The slave latch includes a primary inverter and a feedback inverter. Expediently, a transmission gate between the master-latch and the slave-latch is eliminated. The primary inverter in the slave-latch is not gated to prevent the input of the feedback inverter from going into a “floating” state.

### FIELD OF THE INVENTION

The present invention relates generally to the field of integrated circuits and, more specifically, to methods and systems that allow for reducing leakage power and area consumption of flip-flops

### BACKGROUND OF THE INVENTION

As integrated circuit technology progresses, CMOS based integrated circuits are being scaled extensively. With extensive scaling, the leakage power in integrated circuit elements such as flip-flops also becomes significant. Simulations conducted on a typical microcontroller family estimate that about 30% reduction in flip-flop power consumption translates to about 6% power reduction for the entire integrated circuit.

Reference is made to a prior art type conventional D flip-flop with scan functionality as shown in FIG. 1. Clocked flip-flops in integrated circuits generally work by utilizing sequential logic to selectively latch one of two binary states, a logic “0” or a logic “1”. A D flip-flop inputs a binary data input D and in response to clock transitions thereafter outputs D at a binary data output Q. Typical flip-flops of this type use a master and a slave section with the master section initially clocked on one level of a clock signal to store the logic state from input D on a master node, and then, on the next level of the clock, to transfer this logic state to a slave node for storage and also to output it on the Q output. In this manner, on the next clock cycle, another logic state can be stored on the master node without affecting the slave node. As illustrated, FIG. 1 shows a standard D flip-flop with scan functionality. The Master-latch in this flip-flop 110 has a first pair of inverters 111 and 112. These inverters are always on, irrespective of the output Q being driven by the slave-latch 120 or the master-latch 110. As gate leakage is particularly prominent in sub-100 nm technologies, it is noted that these inverters 111 and 112 carry a resistive component along with a capacitive component as the load. Hence, even under static conditions, there is a considerable amount of power leakage which is undesirable.

The power leakage in integrated circuit flip-flops is a problem and is deleterious especially for battery-operated portable devices. Owing to leakage, batteries get drained even when the devices are not in use. This in turn degrades the effective battery life. Even for wall-plugged devices running on AC/DC power, leakage power dissipation via flip-flops causes reliability concerns and might result in increased packaging costs. Some publications related to the field of this invention include: a: Accurate stacking effect Macro-modeling of Leakage Power in Sub—100 nm Circuits; b: Principles of CMOS VLSI Design—Neil Weste and Kamran Eshraghian, and, c: Digital Integrated Circuits—Jan M. Rabaey, Anantha Chandrakasan, Borivoje Nikolic.

### SUMMARY OF THE INVENTION

The invention in one form resides in an integrated circuit including a flip-flop of the type that has a master-latch and a slave latch using clock signals and an output, the master latch having first and second inverters, said flip-flop comprising: circuitry for reducing leakage power, comprising gating circuitry for selectively gating the first and second inverters to render them inactive when an output of the flip-flop is driven by the slave latch. The invention in a modification resides in a battery operated portable device that incorporates an integrated circuit with a flip-flop as recited hereinabove. The flip-flop may be a D flip-flop which is incorporated in a portable device having an MOS based integrated circuit.

The invention in another form resides in a method of reducing leakage/standby power in a battery operated portable device which uses a flip-flop of the type that has a master-latch with first and second inverters and a slave-latch and uses a clock, comprising the steps of: providing first and second transistors each having a gate electrode and connected to receive an inverted clock signal; and, connecting said first and second transistors to selectively gate said first and second inverters such that the first and second inverters are inactive when an output of the flip-flop is driven by the slave-latch.

In another form, the invention resides in a programmed device having a program thereon which when executed on a computing platform for reducing leakage/standby power in a flip-flop of the type that has a master-latch with first and second inverters and a slave-latch and uses a clock, executes the method steps comprising: providing first and second transistors each having a gate electrode and connected to receive an inverted clock signal; and, connecting said first and second transistors to selectively gate said first and second inverters such that the first and second inverters are inactive when an output of the flip-flop is driven by the slave-latch.

### BRIEF DESCRIPTION OF THE DRAWINGS

These and other features and advantages of the present invention will be further appreciated, as they become better understood by reference to the detailed description when considered in conjunction with the accompanying drawings:

FIG. 1 is a diagram depicting a prior art D flip-flop;

FIG. 2 is a diagram depicting a flip-flop system according to an embodiment of the present invention;

FIG. 3 is a detailed electrical layout of the flip-flop according to an embodiment of the present invention; and,

FIGS. 4a and 4b illustrate an exemplary operational flow in the system of present invention for the cases when the clock is low and high, respectively.

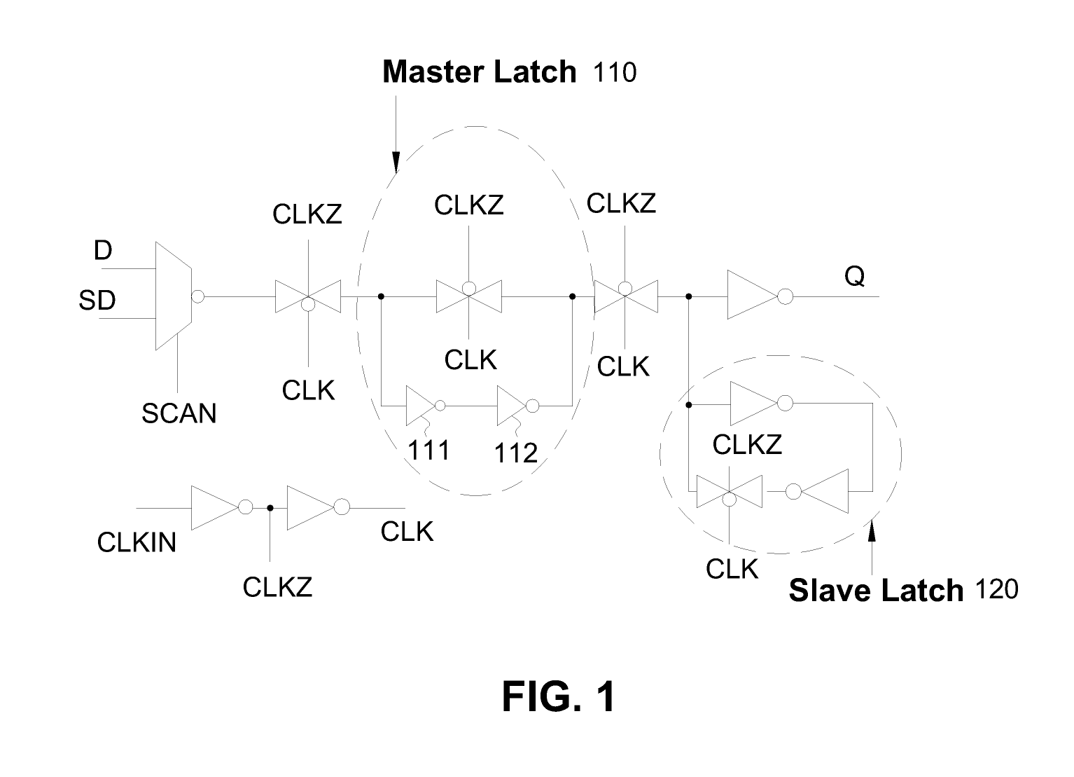

### DETAILED DESCRIPTION OF THE INVENTION

The present invention discloses a method and system for reducing the standby power consumption of a D flip-flop, such that it not only improves performance of integrated circuits as a whole, but also area reduction of the flip-flop, resulting in a smaller and more efficient integrated circuit design. Various modifications to the preferred embodiment will be readily apparent to those of ordinary skill in the art, and the disclosure set forth herein may be applicable to other embodiments and applications without departing from the spirit and scope of the present invention and the claims appended hereto. Thus, the present invention is not intended to be limited to the embodiments described, but is to be accorded the broadest scope consistent with the disclosure set forth herein.

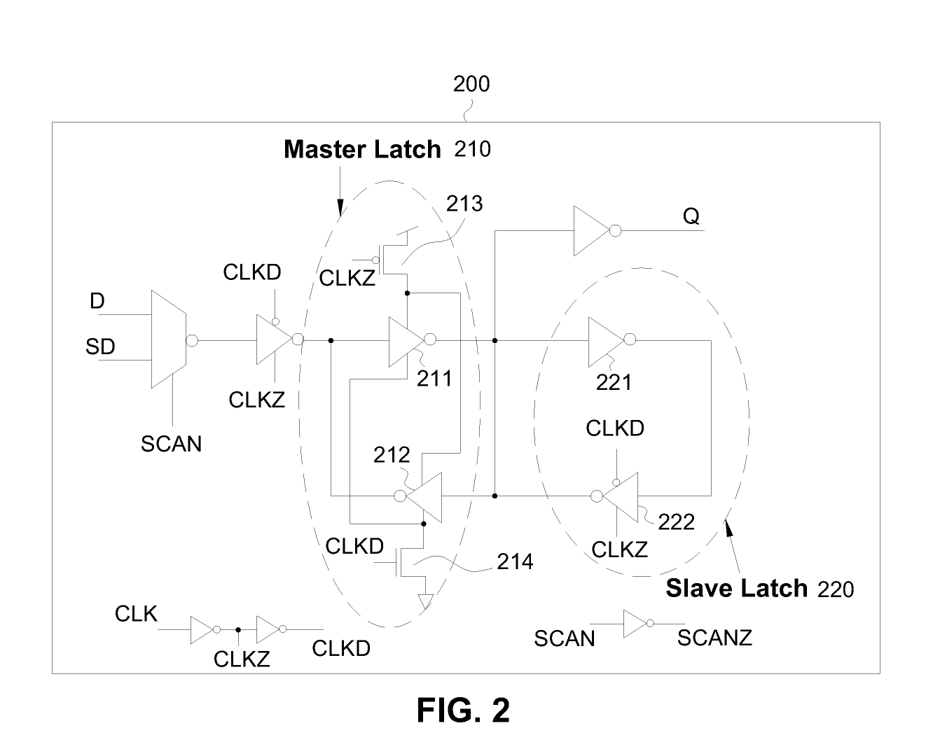

Referring to FIG. 2, one embodiment of the present invention is shown. The invention comprises a flip-flop 200 designed in a low standby power configuration. As shown, the flip-flop 200 comprises a master section, also referred to as master-latch 210 and a slave section, comprising the slave-latch 220. The master-latch comprises a pair of inverters 211 and 212. In a preferred embodiment, the inverters 211 and 212 in the master-latch are gated by connecting with transistors 213 and 214. This design enables cutting off the power supply to the inverters 211 and 212 when the clock is low. The slave-latch 220 comprises a primary inverter 221 and a feedback inverter 222. Unlike the inverters in the master-latch, the primary inverter 221 in the slave-latch is not gated. This prevents the input of the feedback inverter 222, which is next in line after the primary inverter, from going into a “floating” state. In one embodiment, each of the inverters in the flip-flop 200 comprises a series circuit of a p-channel and an n-channel transistor coupled between a voltage source and ground potential.

One of ordinary skill in the art would appreciate that the preferred design of the present invention eliminates the need for a transmission gate between the master-latch and the slave-latch, which is typically present in a conventional flip-flop design. This reduces the total number of transistors required to realize the D flip-flop functionality by two, and thus makes the design of the present invention more area-conserving.

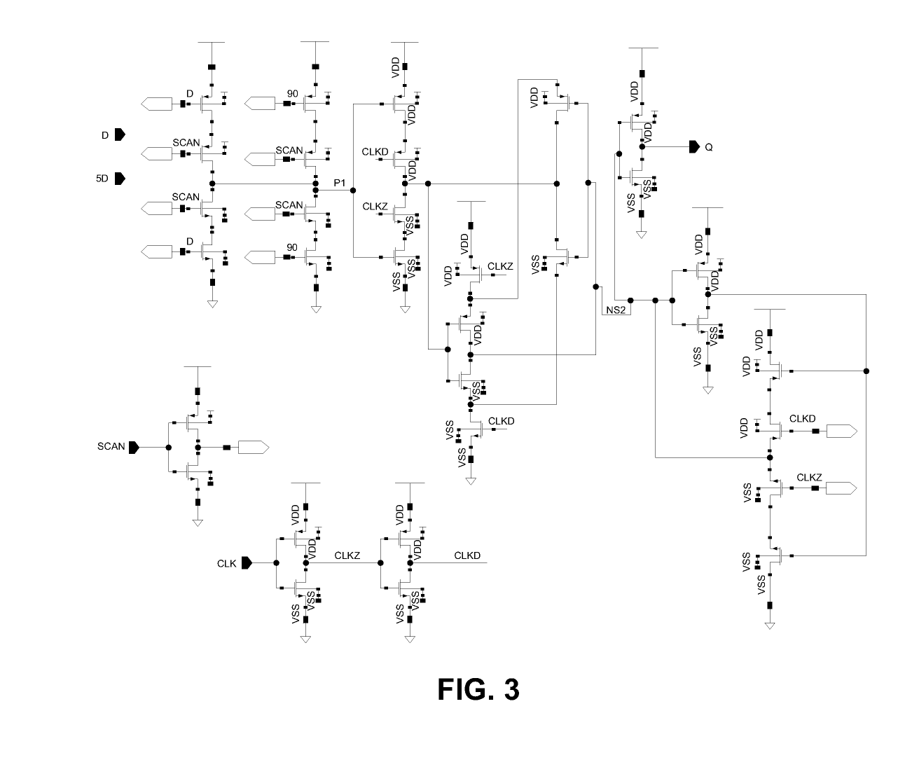

FIG. 3 is a detailed electrical layout corresponding to the low standby power flip-flop depicted in FIG. 2. As can be seen from the FIGS. 2 and 3, routing in the electrical layout is simplified as the number of transistors is reduced. Also, the layout is designed in a manner such that all the devices in the flip-flop, excluding the inverter 221 in the slave-latch 220, are stacked. This stack effect reduces leakage, based on the principle that two “off” MOSFETs in a series account for less leakage as compared to a single “off” MOSFET.

As previously mentioned, the inverter 221 in the slave-latch 220 is not gated to prevent the input of the next inverter, which is a feedback inverter 222, from going into a “floating” state. This non-gated inverter in the slave-latch is provided with a higher channel length MOSFET. This feature further aids the reduction of power leakage.

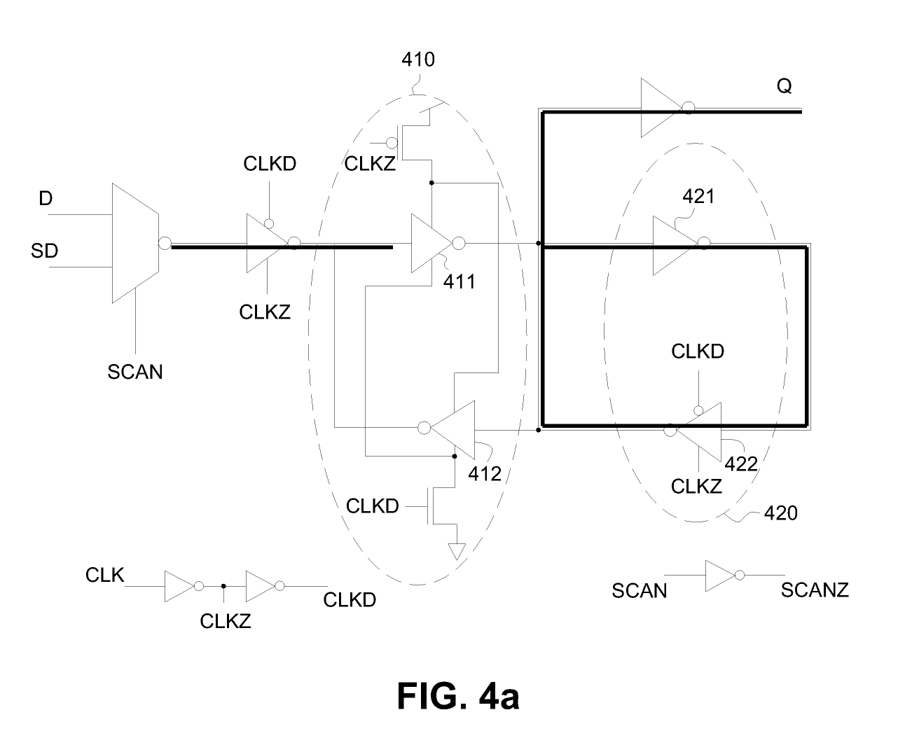

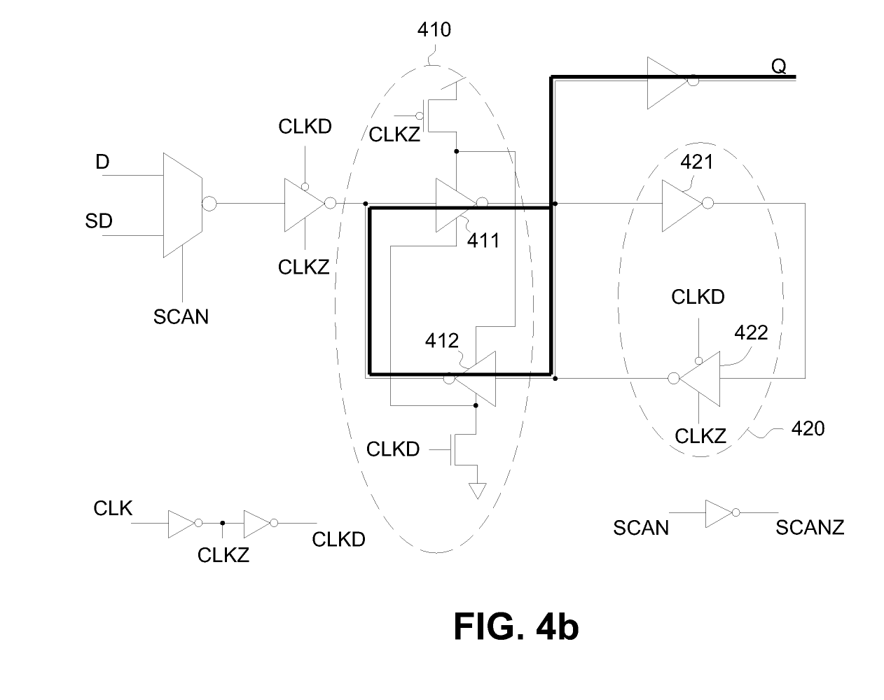

Referring to FIGS. 4a and 4b, the working of the flip-flop of the present invention is described. Thus, as illustrated in FIG. 4a, when the clock (CLK) is Low (voltage level zero), CLKZ is high and CLKD is low. Therefore, both the inverters 411 and 412 in the master-latch 410 are not active, and the output Q is driven by the slave-latch 420. The operational path from the input to output is highlighted by means of bold lines in FIG. 4a.

Referring to FIG. 4b, the working of the flip-flop when the clock (CLK) is High (voltage level one) is described. In this case, CLKZ is low and CLKD is high. Thus, the output Q is driven by the master-latch 410. One of ordinary skill in the art would appreciate that even though the output is driven by the master-latch 410 when the clock is high, the primary inverter 421 in the slave latch is not inactive. This inverter is kept active to prevent the input of the next inverter 422 in the slave-latch 420 from floating.

The table depicted herein delineates a comparison of performance of the flip-flop of an embodiment of the present invention with a prior art flip-flop.

TABLE 1

| | | | | | Only | | |
|---|---|---|---|---|---|---|---|
| | | | | Only | CLK | | Clock to Q |
| | | CLK to | | CLK | toggles | | (fall)/ |
| | | Q power | | toggles | without | | Clock to Q |
| | | (pJ) | Only D | without | Q | | (rise) |
| | Average | Output | toggles | Q | toggling | setup0/setup1 | (ps) |
| | Leakage | Load 2 SL. | (pJ) | toggling | (pJ) | (ps) | CLK slew 200 ps |
| | Power | CLK slew | Data slew | CLK slew | CLK slew | CLK slew 200 ps | DATA slew 200 ps |
| Cell | (pW) | 200 ps | 200 ps | 200 ps | 1 ns | DATA slew 200 ps | Load of 5SL |
| Existing 1x Flip-flop (TDN10Q) | 1.11E+05 | 5.53 | 12.268 | 10.77 | 22.46 | 214.4/180.3 | 147.3/171.9 |
| Low Standby Power Flip-flop | 8.45E+04 | 8.09 | 9.726 | 7.07 | 11.35 | 192.8/75.4 | 220.9/253.2 |
| Gain/Loss | 23.60% | −46.30% | 20.80% | 34.40% | 49.50% | 10.07%/58.18% | −49.9%/−47.2% |

Table 1 above shows a comparison of various performance metrics for the low standby power flip-flop of the present invention with those for a flip-flop from a standard library, such as a 90 nm 1× drive flip-flop. The comparison is done at 125 C, 1.08 Volts. It is apparent from the table that the standby power of the flip-flop of the present invention is reduced as the average leakage power is decreased by about 23.6% as compared to a flip-flop that does not include the low standby power technique of the present invention. Furthermore, two other significant metrics—data toggling power and “clock toggling without output toggling” power are also considerably reduced. While data toggling power is decreased by approximately 20.8%, the “clock toggling without output toggling” power reduces in the range of about 34.4% (at 200 ps clock slew) to 49.5% (at ins clock slew). Thus, the flip-flop is substantially static and does not encounter any functionality problems even while operating at a very bad clock slew.

The performance analysis data for the flip-flop of the present invention has shown that the flip-flop is functional at about 2 ns (rail-to-rail) clock slew at low voltage, weak corner and at about 1.8 ns clock slew at high voltage, strong corner.

Although one of the performance metrics, the “clock to Q delay” shows degradation, however, overall performance is improved as the setup0 and setup1 time metrics improve by about 10% and 58% respectively. Moreover, since the design topology of the present invention utilizes two transistors less than a conventional flip-flop, it makes for a more compact and area conserving design. The flip-flop area is effectively reduced by 3.46% approximately as compared to the 1× flip-flop in the standard library. Hence, the flip-flop of the present invention is of considerable use in non-critical paths where timing is not a big concern. It is to be noted that the invention includes a programmed device having a program thereon which when executed on a computing platform for reducing leakage/standby power in a flip-flop of the type that has a master-latch with first and second inverters and a slave-latch and uses a clock, executes the method steps of operating the flip-flop as taught herein.

Some of the advantages of the novel flip-flop configuration described above as compared with the prior art D flip-flop, for example, include:

1. 23.6% lower average leakage power,

2. 20.8% lower data toggling power,

3. 34.4% (at 200 ps clock skew) to 49.5% (at ins clock skew) lower “clock toggling and output remaining at the same state” power,

4. 3.46% lower area,

5. 2 fewer transistors, and improved setup 0/setup 1 by 10 to 58%.

The above examples are merely illustrative of the many applications of the system of present invention. Although only a few embodiments of the present invention have been described herein, it should be understood that the present invention might be embodied in many other specific forms without departing from the spirit or scope of the invention. Therefore, the present examples and embodiments are to be considered as illustrative and not restrictive, and the invention may be modified within the scope of the appended claims and their equivalents.

1. A method of reducing leakage/standby power in a flip-flop of the type that has a master-latch with first and second inverters and a slave-latch and uses a clock, comprising:
providing first and second transistors each having a gate electrode and connected to receive an inverted clock signal; and,
connecting said first and second transistors to gate said first and second inverters such that the first and second inverters are inactive when an output of the flip-flop is driven by the slave-latch.

2. The method as in claim 1, including the step of configuring said first and second inverters to be active when the output of the flip-flop is driven by the master-latch.

3. The method of claim 1, wherein said flip-flop comprises a D flip-flop, wherein said first and second transistors comprise a p-channel transistor and an n-channel transistor respectively, and including the step of connecting the first and second transistors in a series circuit between a voltage source and ground.

4. An integrated circuit including a flip-flop of the type that has a master-latch and a slave latch using clock signals and an output, the master latch having first and second inverters, said flip-flop comprising:
circuitry for reducing leakage power, comprising gating circuitry for gating the first and second inverters to render them inactive when an output of the flip-flop is driven by the slave latch.

5. The integrated circuit as in claim 4, wherein said gating circuitry comprises first and second transistors which comprise respectively a p-channel transistor and an n-channel transistor.

6. The integrated circuit as in claim 5, wherein said and second transistors are connected in a series circuit between a voltage source and ground.

7. A battery powered portable device including a flip-flop of the type that uses clock signals and has a master-latch, a slave latch and an output, the master latch having first and second inverters, said flip-flop comprising:
circuitry for reducing leakage power, comprising gating circuitry for gating the first and second inverters to render them selectively inactive when the output of the flip-flop is driven by the slave latch.

8. The battery powered portable device as in claim 7, wherein said gating circuitry comprises first and second transistors which comprise respectively a p-channel transistor and an n-channel transistor.

9. The battery powered portable device as in claim 8, wherein said and second transistors are connected in a series circuit between a voltage source and ground.

10. The battery powered portable device as in claim 9, wherein the flip-flop comprises a D flip-flop.

11. The battery powered portable device as in claim 10, wherein the D flip-flop has scan functionality.

12. The battery powered portable device as in claim 7, wherein the flip-flop is part of an MOS integrated circuit.

13. The battery powered portable device as in claim 12, for use in sub-100 nm technology applications.

14. A programmed device having a program thereon which when executed on a computing platform for reducing leakage/standby power in a flip-flop of the type that has a master-latch with first and second inverters and a slave-latch and uses a clock, executes method steps comprising:
providing first and second transistors each having a gate electrode and connected to receive an inverted clock signal; and,
connecting said first and second transistors to gate said first and second inverters such that the first and second inverters are inactive when an output of the flip-flop is driven by the slave-latch.

15. A battery operated portable device having an MOS based integrated circuit incorporating a flip-flop, wherein the flip-flop comprises:
a master latch comprising a first pair of inverters, a first transistor having a gate electrode for receiving a clock signal and a second transistor having a gate electrode for receiving an inverted clock signal; and
a slave latch comprising a second pair of inverters,
wherein each of said inverters in the first pair of inverters of the master latch is connected to said first and second transistors such that each of said inverters in the first pair of inverters is inactive when an output of the flip-flop is driven by the slave latch.

16. The battery operated portable device of claim 15, wherein each of said inverters in the master latch is active when the output of the flip-flop is driven by said master latch.

17. The battery operated portable device of claim 1, wherein each of said inverters includes a series circuit of a p-channel and an n-channel transistor coupled between a voltage source and a ground terminal.

18. A method of operating a flip-flop, wherein the flip-flop has an output and comprises a master latch including a first pair of inverters, a first transistor having a gate electrode for receiving a clock signal, and a second transistor having a gate electrode for receiving an inverted clock signal, and wherein the flip-flop further comprises a slave latch including a second pair of inverters, the method comprising: connecting each of said inverters in said first pair of inverters of the master latch to said first and second transistors in such a manner that each of said inverters in said first pair of inverters is inactive when the output of the flip-flop is driven by the slave latch.

19. The method of claim 18, wherein, in use, each of said inverters in the first pair of inverters of the master latch is active when the output of the flip-flop is driven by said master latch.

20. The method of claim 18, wherein, each of said inverters in the first pair of inverters in the master latch includes a series circuit of a p-channel and an n-channel transistor coupled between a voltage source and a ground terminal.
